(19) United States
(12) Patent Application Publication
(10) Pub. No.: US 2026/0093890 A1
(43) Pub. Date: Apr. 2, 2026

(54) TIE NET SPLITTING FOR ROUTERS

(71) Applicant: International Business Machines Corporation, Armonk, NY (US)

(72) Inventor: Niko Sebastian Klewinghaus, Bonn (DE)

(21) Appl. No.: 18/902,999

(22) Filed: Oct. 1, 2024

(51) Int. Cl. G06F 30/394; G06F 30/392

(52) U.S. Cl. CPC G06F 30/394; G06F 30/392

(57) ABSTRACT

Embodiments of the invention are directed to a computer-implemented method of performing circuit design operations. The computer-implemented method includes defining, using a processor system, relevant tiles of an electronic version of a circuit design. A grouping operation is performed on the relevant tiles to define relevant-tile groups. Iterations of a tie-pin routing operation are performed. Each of the iterations of the tie-pin routing operation include identifying an initial or next relevant-tile group; and routing tie-pins of the initial or next relevant-tile group to a segment of a power grid of the circuit design of the initial or next relevant-tile group, where the tie-pins of the initial or next relevant-tile group and the segment of the power grid of the circuit design are within a relevant-tile group region of the initial or next relevant-tile group.

### BACKGROUND

The present invention relates in general to electronic design tools used to assist with integrated circuit (IC) design. More specifically, the present invention relates to computing systems, computer-implemented methods, and computer program products that implement novel tie net routing techniques operable to customize trade-offs between parallel run time and performance considerations during IC design routing operations.

In IC design, a net defines the connections between instance terminals that implement the logic of the design being implemented. To ensure correct behavior, the values of unused or floating gate inputs are set to a known state (e.g., either a logical zero (0) or logical one (1)) by connecting such gate inputs to either the ground supply or the power supply. Each instance of such a gate input is referred to as being “tied,” and the connections that form the ties are referred to as tie nets. Tie net modeling is a technique performed by router software during the place-and-route process of IC design operations to connect tie nets.

### SUMMARY

Embodiments of the invention are directed to a computer-implemented method of performing circuit design operations. The computer-implemented method includes defining, using a processor system, relevant tiles of an electronic version of a circuit design. A grouping operation is performed on the relevant tiles to define relevant-tile groups. Iterations of a tie-pin routing operation are performed. Each of the iterations of the tie-pin routing operation include identifying an initial or next relevant-tile group; and routing tie-pins of the initial or next relevant-tile group to a segment of a power grid of the circuit design of the initial or next relevant-tile group, where the tie-pins of the initial or next relevant-tile group and the segment of the power grid of the circuit design are within a relevant-tile group region of the initial or next relevant-tile group.

Embodiments of the invention are also directed to computer systems and computer program products having substantially the same features, technical effects, and technical benefits as the computer-implemented methods described above.

Additional features and advantages are realized through techniques described herein. Other embodiments and aspects are described in detail herein. For a better understanding, refer to the description and to the drawings.

### BRIEF DESCRIPTION OF THE DRAWINGS

The subject matter which is regarded as embodiments is particularly pointed out and distinctly claimed in the claims at the conclusion of the specification. The foregoing and other features and advantages of the embodiments are apparent from the following detailed description taken in conjunction with the accompanying drawings in which:

FIG. 1 depicts an exemplary computing environment operable to implement aspects of the invention;

FIG. 2 depicts a simplified block diagram illustrating an electronic design automation (EDA) system operable to implement aspects of the invention;

FIG. 3 depicts a simplified block diagram illustrating a side-view of an IC (e.g., a high-speed very large scale integrated IC (VLSI IC)) having interconnect structures that can be designed and routed using embodiments of the invention;

FIG. 4A depicts a simplified block diagram illustrating a top-down view of global power rails of a power rail network that can be utilized in embodiments of the invention;

FIG. 4B depicts a simplified block diagram illustrating a top-down view of local power rails of a power rail network that can be utilized in embodiments of the invention;

FIG. 5 depicts a simplified block diagram illustrating a top-down view of power staples of a power staple network that can be utilized in embodiments of the invention;

FIG. 6 depicts a simplified block diagram illustrating a top-down view of a power grid that can be utilized in embodiments of the invention;

FIG. 7A depicts a simplified block diagram illustrating a top-down view of a candidate tile network that can be utilized in embodiments of the invention;

FIG. 7B depicts a simplified block diagram illustrating a top-down view and a side-view of a candidate tile that can be utilized in embodiments of the invention;

FIG. 8 depicts a simplified block diagram illustrating a top-down view of the power grid show in FIG. 6, along with a top-down view of the candidate tile network shown in FIG. 7A;

FIG. 9 depicts a simplified block diagram illustrating a top-down view of relevant tile groups that are utilized in embodiments of the invention;

FIG. 10 depicts a simplified block diagram illustrating a top-down view of relevant tile groups, associated net shapes (not shown separately), and associated power grid segments that are utilized in embodiments of the invention;

FIG. 11A depicts a simplified block diagram illustrating another top-down view of relevant tile groups that are utilized in embodiments of the invention;

FIG. 11B depicts a simplified block diagram illustrating a top-down view of a relevant tile and a side view of the same relevant tile utilized in embodiments of the invention;

FIG. 11C depicts a methodology in accordance with embodiments of the invention;

FIG. 11D depicts constraints associated with the methodology depicted in FIG. 11C;

FIG. 12 depicts a block diagram of a system capable of designing an IC using embodiments of the invention; and

FIG. 13 is a process flow of a method of fabricating an IC designed using embodiments of the invention.

To provide spatial (or three-dimensional) context to different structural orientations of the semiconductor structures shown in the figures, XYZ Cartesian coordinates are provided in some of the figures.

In the accompanying figures and following detailed description of the disclosed embodiments, some of the elements illustrated in the figures are provided with reference numbers. In some instances, the leftmost digit of each reference number corresponds to the figure in which its element is first illustrated.

### DETAILED DESCRIPTION

Turning now to an overview of technologies that are relevant to and support aspects of the invention, ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that electronically couple to active regions (e.g., gate, source, and drain) of the device element. BEOL layers use insulating and stabilizing dielectric materials embedded with a network of wires, lines and vias (i.e., interconnects) that couple current to FEOL and MOL layers to complete the IC. The conductive interconnect layers formed during the BEOL stage serve as a network of pathways that transport signals throughout an IC, thereby connecting circuit components of the IC into a functioning whole and to the outside world. Because there typically is not enough room on the chip surface to create all of the necessary connections in a single layer, chip manufacturers build vertical levels of interconnects. While simpler ICs can have just a few metallization layers, complex ICs can have ten or more layers of wiring.

BEOL-stage interconnect structures that are physically close to FEOL-stage components (e.g., transistors and the like) need to be small because they attach/join to the components that are themselves very small and often closely packed together. These lower-level lines, which can be referred to as local interconnects, are usually thin and short in length. Global interconnects are higher up in the IC layer structure and travel between different blocks or cells of the circuit. Thus, global interconnects are typically thick, long, and more widely separated than local interconnects. Vertical connections between interconnect levels (or layers) are known as metal-filled vias and allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

In complex and dense ICs (e.g., VLSI ICs), thousands to billions of transistors and other devices are present on a single chip, and these ICs/chips are configured to implement complex structures/functions, such as microprocessors, memory chips, or system-on-chip (SoC) designs. Because it is not practical or, under some circumstances, not possible to manually execute the design tasks (e.g., signal timing, metal density, signal integrity, and the like) required for acceptable design & manufacturing runtimes to create complex and dense ICs, software/hardware known as “electronic design automation” (EDA) systems or tools have been developed to assist with a variety of electronic system design operations, including, for example, so-called “place and route” operations that map out the placement of electronic components/circuitry, along with the routing of interconnect structures needed to connect the placed components/circuitry.

The terms “place and route” refer to design stages of electronic systems such as ICs and printed circuit boards (PCBs) that map out the placement of electronic components/circuitry, along with the routing of interconnect structures needed to connect the placed components/circuitry. Placement operations involve deciding where to place all electronic components, circuitry, and logic elements in a generally limited amount of space. An inferior placement assignment will not only affect the chip's performance but might also make it non-manufacturable by producing excessive wire-length, which is beyond available routing resources. Thus, the placement operation(s) must be performed while optimizing a number of objectives to ensure that a circuit meets its performance demands. Placement operations take a given synthesized circuit netlist together with a technology library and produces a valid placement layout. In electronic design, a netlist is a description of the connectivity of an electronic circuit. In its simplest form, a netlist includes a list of the electronic components in a circuit and a list of the nodes they are connected to. The layout is optimized according to the aforementioned objectives and made ready for cell resizing and buffering, which are used to achieve timing and signal integrity satisfaction.

Placement operations are followed by routing operations, which decide the exact design of all the wires needed to connect the placed components. Routing operations build on placement operations to implement all the desired connections while following the rules and limitations of the manufacturing process. The portion of an EDA system that performs routing operations is often referred to generally as a router. In general, routers are provided with some pre-existing polygons that represent pins (also called terminals) on cells, and optionally some pre-existing wiring called pre-routes. Each of the polygons is associated with a net, usually by name or number. The primary general task of the router is to create geometries such that all terminals assigned to the same net are connected, no terminals assigned to different nets are connected, and all design rules are obeyed. A router can fail by not connecting terminals that should be connected (an open), by mistakenly connecting two terminals that should not be connected (a short), or by creating a design rule violation. In addition, to correctly connect the nets, routers can also ensure that the IC design meets timing, has no crosstalk problems, meets any metal density requirements, does not suffer from antenna effects, and so on. The objectives a router seeks to satisfy can be numerous and are often conflicting, which makes routing extremely difficult. Routers, therefore, do not attempt to find an optimum result, but are instead based on heuristics, which try to find a solution that is good enough.

The electronic components/circuity of an IC design can be organized as cells with different functions. For example, cells can be logic gates, such as an AND gate, an OR gate, combinational logic circuits such as a multiplexer, a flip-flop, an adder, a counter, and the like. Cells can be selected and arranged to realize complex IC functions. For convenience of IC design, cell libraries can be established to include frequently used cells with their corresponding layouts. Therefore, when designing an IC, desired cells can be selected from the library and placed in an automatic placement and routing block, such that a layout of the IC can be created.

In instances where there is a hierarchical relationship between IC/PCB components, the component that sets the requirements (e.g., timing requirements or other constraints) for another component is known as the “parent,” and the component that has its requirements (e.g., timing requirements or other constraints) set by another component is known as the “child.” It is often a priority in IC designs to re-use as many IC/PCB components as possible, which means that a given component is often deployed at multiple locations throughout the IC. The multiple locations can be within the same chip of the IC or across multiple different chips of the IC. Thus, a re-used component can be a child component to multiple different parent components, which means that the child components will need to satisfy multiple, potentially competing constraints that come from multiple different parent components.

As previously described herein, the term “net” is often used to refer to a collection of electrically connected components or nodes (e.g., transistors, resistors, capacitors, and the like) that are tied together to form a functional circuit. In many instances, the term “net” simply refers to how the electrical pathways between different parts of the IC design are distributed. Nets can be used for different purposes. For example, so-called signal nets carry signals between different parts of the IC design; and power nets (e.g., power rails or supply nets) distribute electric power (e.g., voltage) to different parts of the IC design.

A netlist is a detailed list or description of all the nets in a circuit. Netlists are used as a reference for various relevant IC design operation, including placement, routing, layout and verification. For example, in the routing phase of IC design, the physical representation of nets is created by defining the metal layers and paths that connect the components of the IC design, thereby ensuring that the IC design is both functional and manufacturable. Nets must adhere to certain design rules to ensure proper electrical performance, manufacturability, and reliability. Design rules govern IC design aspects such as spacing, width, and the avoidance of electrical shorts or opens.

To ensure correct behavior, the values of unused or floating gate inputs are set to a known state (e.g., either a logical zero (0) or logical one (1)) by connecting such gate inputs to either the ground supply or the power supply. Each instance of such a gate input is referred to as being “tied,” and the connections that form the ties are referred to as tie nets. Tie net modeling is a technique performed by router software during the place-and-route process of IC design operations to connect tie nets.

As the size of ICs has continued to be reduced, there is increasing pressure on IC designs have fewer metal layers, which places increasing pressure on how an IC design utilizes metal layers, including power rails. It is a challenge to decrease the size and number of metal layers in IC designs while increasing the utilization of metal layers in IC designs without increasing routing congestion, increasing cross talk noise, and decreasing resistance/capacitance (RC) performance. RC performance is particularly important for relatively smaller IC designs. As IC size decreases, and IC density increases, the RC contribution of interconnect networks to the RC characteristics of the IC design become more important. In ICs, the RC characteristics throughout the IC design influence the speed and performance of the IC. High resistance in interconnects can slow down signal propagation by increasing the time required for the voltage to reach its intended value. This delay is often referred to as propagation delay, which can limit the speed of the circuit. Capacitance in ICs refers to the ability of an IC element to store an electrical charge. Capacitance can result from the physical layout of the interconnects, the dielectric materials used to surround and stabilize the interconnects, and the proximity of other conductive IC elements. High capacitance increases the time required to charge or discharge a node, thereby contributing to a longer propagation delay, which can negatively impact the IC’s overall speed.

Because tie nets can be very large with many pins that need to be routed or tied to the IC’s power grid, it is particularly challenging to efficiently perform tie net routing. Accordingly, routing a single tie net can take a very long time. Additionally, because tie-pins can be routed to anywhere on the IC power grid, there are many options for how tie-pins are routed to the IC power grid.

Embodiments of the invention provide computing systems, computer-implemented methods, and computer program products that implement novel tie net routing technique/functionality operable to efficiently and effectively customize trade-offs between parallel run time and performance considerations during IC design routing operations. In some embodiments of the invention, an IC design routing algorithm is provided that implements embodiments of the novel tie net routing technique/functionality. In some aspects of the invention, embodiments of the novel tie net routing technique/functionality organizes an electronic version of an IC design into segments referred to herein as tiles or candidate tiles. Each candidate tile is evaluated based at least in part on its spatial relationship between the candidate tile and a tie-pin of the IC design. In some embodiments of the invention, if a tie-pin satisfies a predetermined spatial relationship with respect to a candidate tile, the candidate tile is marked or otherwise reclassified as a “relevant” tile. In some embodiments of the invention, if none of the tie-pins satisfy the predetermined spatial relationship with respect to the candidate tile, the candidate tile is not marked or otherwise reclassified as a “relevant” tile. In some embodiments of the invention, the predetermined spatial relationship corresponds to an electronic tile region defined for a given candidate tile. In some embodiments of the invention, an electronic tile region is defined for the candidate tile currently under evaluation; the predetermined spatial relationship between a tie-pin and a candidate tile is satisfied when at least one of the IC design tie-pin is within the tile region; and the predetermined spatial relationship between the tie-pin and the candidate tile is not satisfied when none of the IC design tie-pins is within the tile region. At this stage of the evaluation performed by the novel tie net routing technique/functionality, a set of relevant tiles, relevant tile regions and their associated tie-pins are identified and associated with one another.

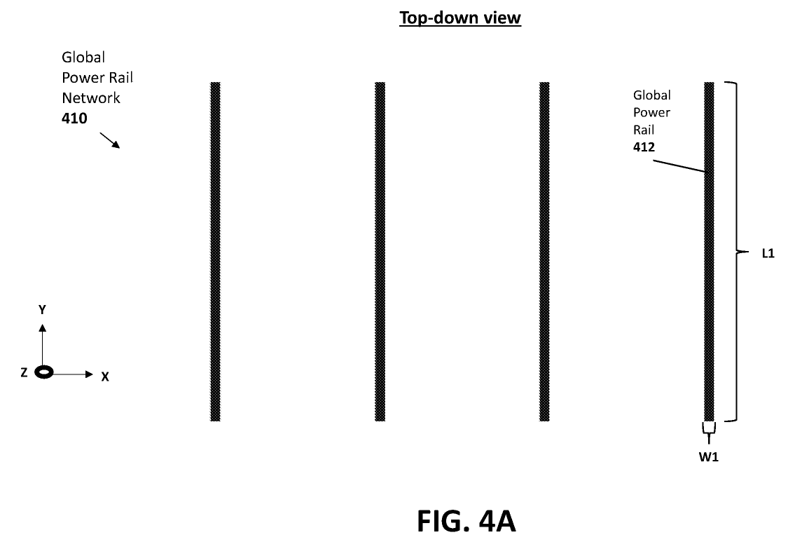

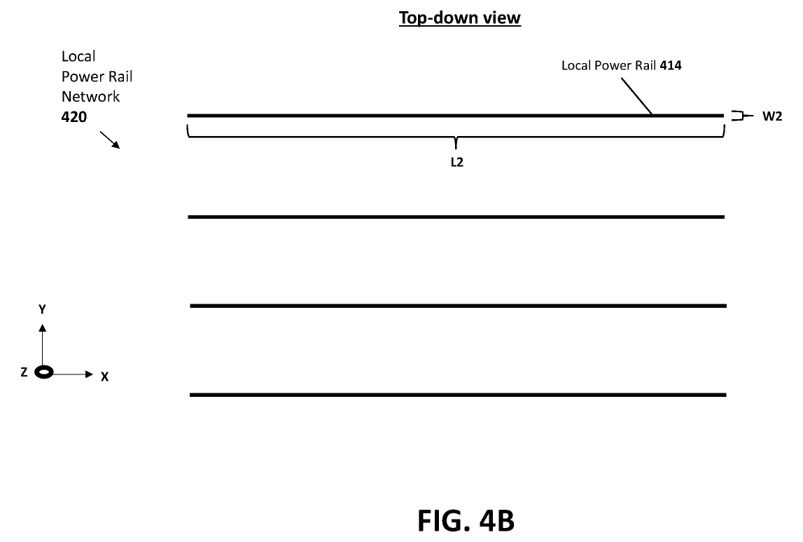

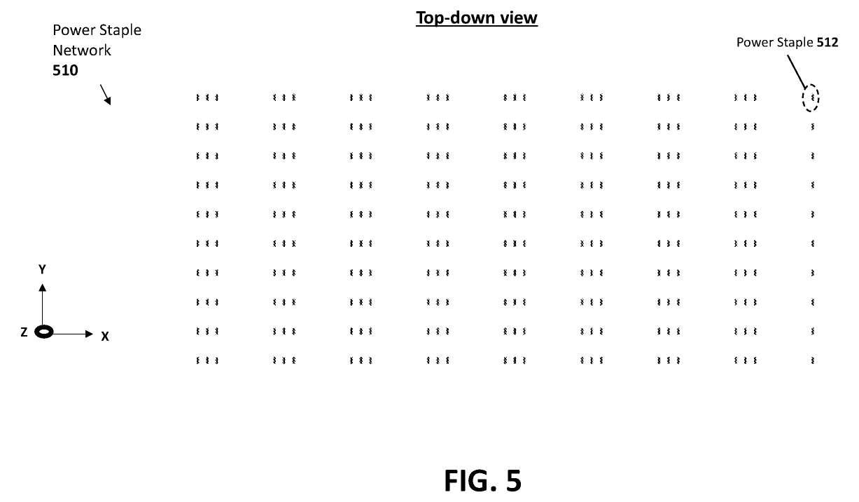

The novel tie net routing technique/functionality also electronically associates each relevant tile with a section of the IC design power grid. Similar to the technique/functionality used to determine the candidate tiles that are marked or classified as relevant tiles, each relevant tile is associated with a selected segment of the IC design power grid, where the selected segment is selected based at least in part on the relevant tile’s spatial relationship with respect to the selected segment of the IC design power grid. In some embodiments of the invention, if a segment of the IC design power grid satisfies a predetermined spatial relationship with respect to the relevant tile, the segment of the IC design power grid is selected, the relevant tile and the selected segment of the IC design power grid are associated with one another, and the portions of the IC design power grid that do not fall within the selected segment of the IC design power grid are not associated with the relevant tile. In some embodiments of the invention, the predetermined spatial relationship corresponds to the electronic tile region defined for a given relevant tile. In some embodiments of the invention, the predetermined spatial relationship between a segment of the IC design power grid and the relevant tile that is currently under evaluation is satisfied by the selected segment of the IC design power grid being within the relevant tile region. At this stage of the evaluation performed by the novel tie net routing technique/functionality, the set of relevant tiles, the associated relevant tile regions, the associated tie-pins, and the associated selected segment of the IC design power grid are all identified and associated with one another. In some embodiments of the invention, constraints are applied to the selection of the segment of the IC design power grid. For example, the novel tie net routing technique/functionality can be prohibited or constrained from selecting a segment of the IC design power grid that splits a power rail of the power grid along its length dimension (e.g., along the L1 dimension shown in FIG. 4A; and/or the L2 dimension shown in FIG. 4B). As another example, the novel tie net routing technique/functionality can be prohibited or constrained from selecting a segment of the IC design power grid that splits a power staple of the power grid along any dimension (e.g., power staples 512 shown in FIG. 5).

The novel tie net routing technique/functionality also electronically associates or groups the relevant tiles based at least in part on a spatial relationship between the relevant tiles. In some embodiments of the invention, the grouping can be performed using a “breadth first search” technique. In embodiments of the invention, the relevant tiles are grouped along with the associated relevant tile regions, the associated tie-pins, and the associated selected segment of the IC design power grid. In some embodiments of the invention, the relevant tiles include tile boundary lines, and the predetermined spatial relationship corresponds to relevant tiles that share a tile boundary line. In some embodiments of the invention, the predetermined spatial relationship is satisfied and relevant tiles are included within a group if the relevant tile shares a tile boundary line with any one of the relevant tiles in the group. At this stage of the evaluation performed by the novel tie net routing technique/functionality, the set of relevant tiles are organized into groups; and the associated relevant tile regions of the group, the associated tie-pins of the group, and the associated selected segment(s) of the IC design power grid of the group are all identified and associated with one another.

The novel tie net routing technique/functionality applies any suitable routing algorithm operable to route the tie-pins in each group to an appropriate location of the segment(s) of the IC design power grid in the same group as the tie-pin. In some embodiments of the invention, the tie-pin routing can be multi-threaded in that each group is routed substantially in parallel. After routing each group, the resulting tie net routes are added to the original tie net of the IC design.

Accordingly, the novel tie net routing technique/functionality can segment tie nets in a way that in most cases allows efficient parallelization of the routing of the tie net while increasing the likelihood (through the predetermined spatial relationships) that there is no loss in performance or quality of the tie net routing solution generated. Alternatively, a guarantee in parallelization efficiency can be obtained by sacrificing a controlled amount of potential solution quality (increase in wire length). Embodiments of the invention partition the routing space into rectangular tiles; mark all tiles that are intersected by a tie-pin or a tie global route; split the power grid at the tile borders; and search connected components on the marked tiles. Embodiments of the invention route each connected component within its associated relevant tile group individually. By tuning tile size (including tile area and tile regions), embodiments of the invention can obtain strong parallelization while substantially increasing the likelihood that there is no loss in quality. Embodiments of the invention can also be forced to split connected components that are too large (e.g., exceed a predetermined tile region size threshold), which sacrifices a limited amount of solution quality and guarantees strong speed gains from parallelization.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

Many of the functional units of the systems described in this specification have been labeled as modules. Embodiments of the invention apply to a wide variety of module implementations. For example, a module can be implemented as a hardware circuit including custom VLSI circuits or gate arrays, off-the-shelf semiconductors such as logic chips, transistors, or other discrete components. A module can also be implemented in programmable hardware devices such as field programmable gate arrays, programmable array logic, programmable logic devices or the like. Modules can also be implemented in software for execution by various types of processors. An identified module of executable code can, for instance, include one or more physical or logical blocks of computer instructions which can, for instance, be organized as an object, procedure, or function. Nevertheless, the executables of an identified module need not be physically located together but can include disparate instructions stored in different locations which, when joined logically together, function as the module and achieve the stated purpose for the module.

The components/modules of the systems illustrated herein are depicted separately for ease of illustration and explanation. In embodiments of the invention, the functions performed by the components/modules can be distributed differently than shown without departing from the scope of the various embodiments of the invention describe herein unless it is specifically stated otherwise.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

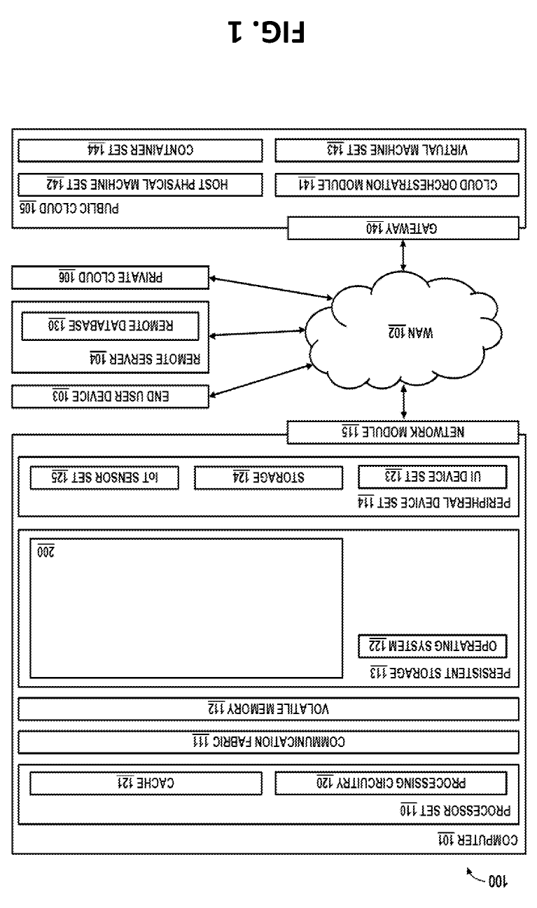

FIG. 1 depicts a computing environment 100 that contains an example of an environment for the execution of at least some of the computer code involved in performing the inventive methods, such as code block 200 operable to implement an EDA system having the novel tie net routing technique/functionality described herein. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

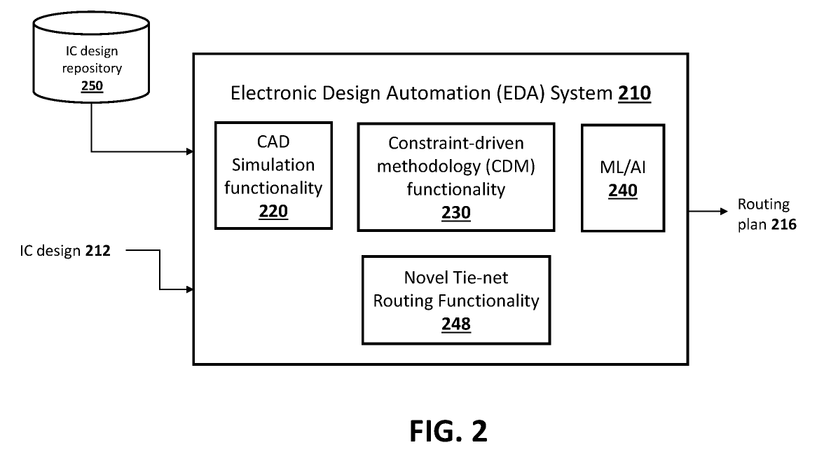

Turning now to a more detailed description of technologies that support and/or implement aspects of the invention, due to the large number of components and the details required by the fabrication process for VLSI ICs, physical design of such ICs is not practical without the aid of computers. As a result, phases of physical design extensively use EDA systems or tools (e.g., EDA system 210 shown in FIG. 2) or computer-aided design (CAD). Using computer functionality to perform physical design processes has increased the level of integration, reduced turn-around time, reduced runtime, and enhanced chip performance.

The processes associated with designing the IC chip are performed on electronic versions of the IC design. In some embodiments of the invention, the electronic version of the IC design can be implemented as register transfer level (RTL) descriptions of the IC design (e.g., IC design 212 shown in FIG. 2). An RTL description is a high-level abstraction used in IC design to describe the operation and behavior of digital circuits. RTL descriptions focus on how data is transferred between registers and how operations are performed on that data. In general, RTL encompasses operations associated with registers, data transfer; operations, clocking, control logic, abstraction levels, description languages, and synthesis. Registers are storage elements that hold data. In RTL, registers are used to store intermediate results and data between operations. Data transfers describes how data moves between registers or between registers and other components, such as ALUs (Arithmetic Logic Units) or memory. For operations, RTL descriptions specify the operations performed on the data, such as addition, subtraction, or logical operations. These operations are usually defined in terms of how they affect the contents of the registers. For clock-related operations, RTL descriptions often include timing details, such as how operations are synchronized with clock signals to ensure that data transfers and operations occur at the correct times. Control logic defines the sequences of operations and data transfers, which is often described using state machines or other control structures, which dictates how the circuit behaves in response to different inputs or conditions. RTL is a higher abstraction level compared to gate-level design, which deals with individual logic gates and their connections. RTL abstracts away the details of gates and focuses on data flow and control. Description Languages: RTL descriptions are commonly written using hardware description languages (HDLs) like VHDL or Verilog. These languages provide syntax and constructs for describing registers, data transfers, operations, and control logic. An RTL description is used as input to synthesis tools that convert the high-level description into a gate-level netlist, which can then be used for physical design and fabrication.

The use of high-level abstraction in IC design allows for a more conceptual approach to designing circuits, which facilitates easier and more effective design, analysis, and verification of complex systems. RTL descriptions are further used in performing physical design to identify and place components such as gate logic. The physical design processes generally begin with logic synthesis, which maps the RTL description to a gate-level netlist (i.e., list of logical interconnects or nets), and end with tape-out and mask generation, which refers to turning the design data into photomasks that are used in the manufacturing process. The physical design processes also include routing, which refers to adding the wires that connect gates and other components to implement the nets of the netlist. Several different programming languages have been created for EDA systems, including Verilog, VHDL and TDML. A typical EDA system (e.g., EDA system 210 shown in FIG. 2) receives one or more high level behavioral descriptions of an IC-under-design (e.g., IC design 212 shown in FIG. 2) and translates this high level design language description into netlists of various levels of abstraction.

FIG. 2 depicts a non-limiting example of an EDA system 210 that can be used to implement aspects of the invention. The EDA system 210 can be implemented using any appropriate combination of the features and functionality of the computing environment 100 (shown in FIG. 1). The EAD system 210 includes computer-aided design (CAD) simulation functionality 220, constraint-driven methodology (CDM) functionality 230, ML/AI functionality 240, and novel tie-net routing functionality 248, configured and arranged as shown. The EDA system 210 is coupled to an IC design repository 250 configured to store electronic information about various aspects of IC designs, including dimensions, shapes, materials, placements, and general performance characteristics.

In embodiments of the invention, the overall EDA system 210 includes CAD simulation functionality 220. CAD is the use of computer-based software to aid in design processes. CAD software is used by engineers and designers to create two-dimensional (2D) drawings or three-dimensional (3D) product-under-development (PUD) models. A purpose of CAD is to optimize and streamline the designer's workflow, increase productivity, improve the quality and level of detail in the design, improve documentation communications, and often contribute toward a manufacturing design database. CAD software outputs can be in the form of electronic files, which are used for manufacturing and/or fabrication processes. CAD can be used in tandem with digitized manufacturing/fabrication processes known as computer-aided manufacturing (CAM) processes. CAD/CAM software can be used to design a variety of products such as electronic circuit boards in computers and other devices. The CAD simulation functionality 220 allows virtual experiments to be performed on an electronic version of the IC design 212 instead of a physical prototype of the IC design 212.

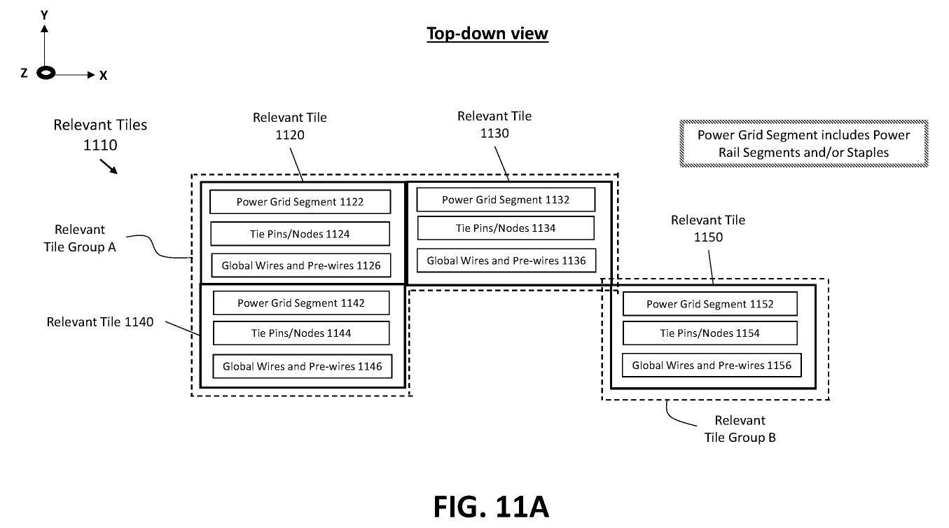

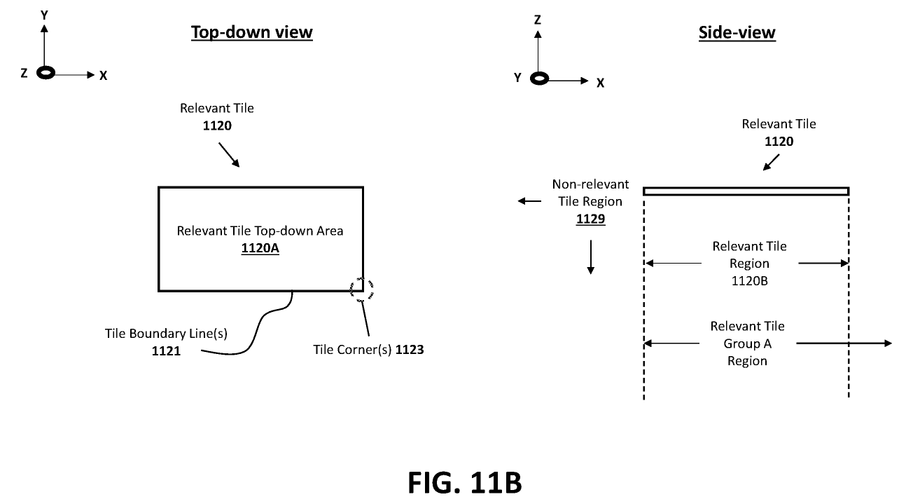

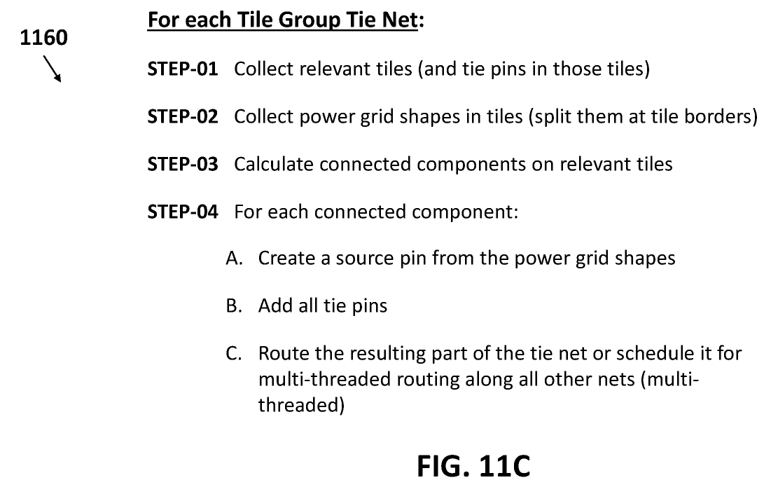

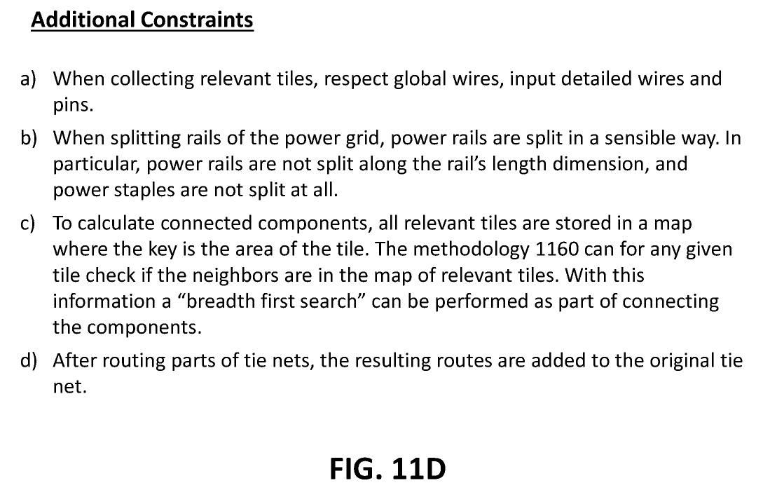

The CDM functionality 230 is a design and optimization approach used in the IC design operations performed by the EDA system 210. The CDM functionality 230 focuses on leveraging constraints (e.g., the additional constraints depicted in FIG. 11D) to guide the design process and ensure that the final IC meets specified performance, power, area, and timing requirements. The EDA system 210 uses the CDM functionality 230 to use the constraints to drive the design process, making adjustments as needed to ensure that the final design adheres to the defined specifications. The design process is iterative, involving multiple rounds of optimization and verification. Constraints are continuously checked and updated as the design evolves. Constraints are propagated through different stages of the design flow. For example, timing constraints might influence the placement of components and routing of signals to ensure that data paths meet timing requirements. By automating the design process and focusing on constraints, the CDM functionality 230 streamlines design efforts and reduces manual intervention, leading to more efficient development. Thus, the CDM functionality 230 is a systematic approach to IC design that emphasizes the use of constraints to guide and optimize the overall design processes performed by the EDA system 210. By leveraging automation tools, iterative optimization, and continuous verification, the CDM functionality 230 can achieve high-performance, reliable, and efficient designs while managing trade-offs (e.g., the tradeoffs associated with the novel tie-net routing functionality 248) and ensuring requirement of the IC design 212 are met.

In some embodiments of the invention, the above-described constraints include the constraints depicted in FIG. 11D and described in greater detail subsequently herein. In some embodiments of the invention, the above-described constraints are developed using historical data about relevant portions of historical IC designs stored in the IC design repository 250. In some embodiments of the invention, the IC design repository 250 can be implemented as a searchable database operable to organize and store data/information of activities and/or events of the historical data about IC designs in segments or regions of the IC design repository 250. The IC design repository 250 can be any form of database, including but not limited to, relational SQL databases, noSQL unstructured databases, unstructured data lakes, time-series databases, and the like. In some embodiments, the IC design repository 250 can include features and functionality of a relational database operably controlled by the computing environment 100 (shown in FIG. 1). In general, a database is a means of storing information in such a way that information can be retrieved from it, and a relational database presents information in tables with rows and columns. A table is referred to as a relational table in the sense that it is a collection of objects of the same type (rows). Data in a table can be related according to common keys or concepts, and the ability to retrieve related data from a table is the basis for the term relational database. A database management system (DBMS) of the computing environment 100 controls the way data in the IC design repository 250 are stored, maintained, and retrieved. A database management system of the computing environment 100 performs the tasks of determining the way data and other information are stored, maintained, and retrieved from the IC design repository 250.

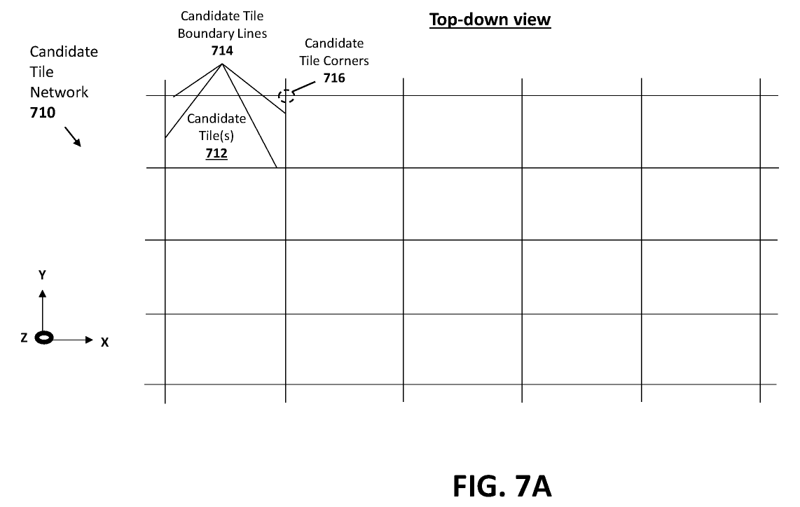

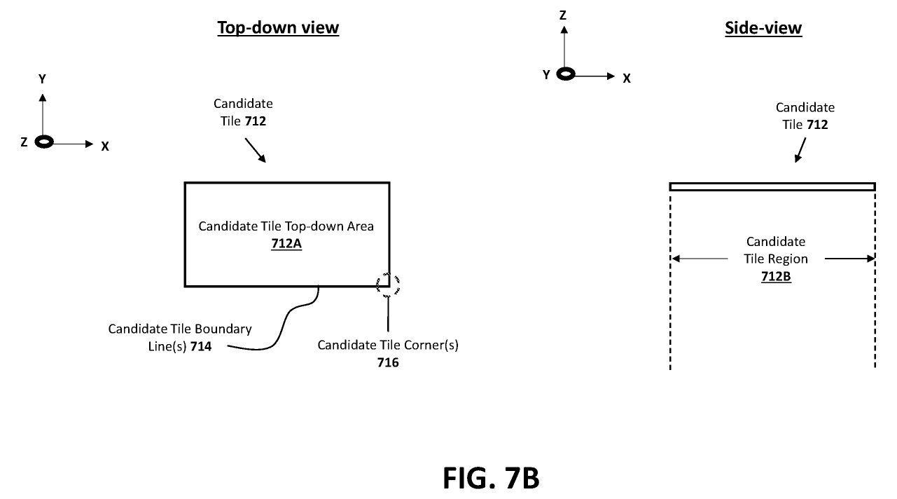

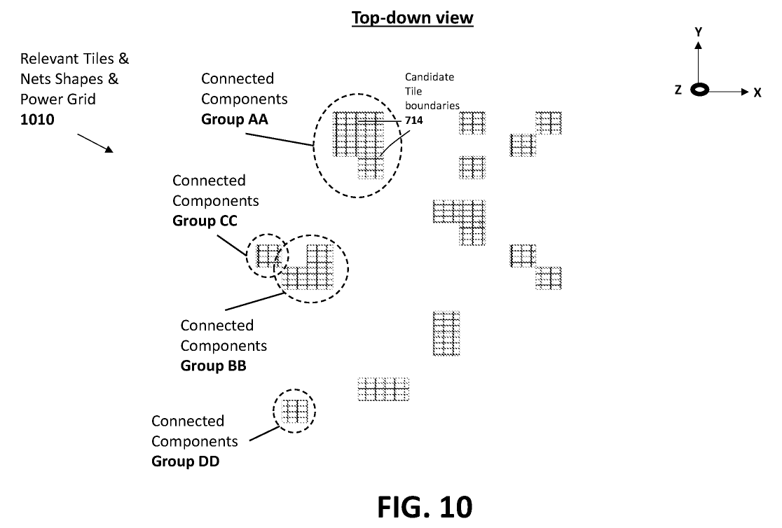

In embodiments of the invention, the EDA system 210, and more specifically, the ML/AI functionality 240, is operable to utilize cognitive algorithms to perform the various data analysis and simulation/prediction operations described herein. In embodiments of the invention, a cognitive algorithm refers to a variety of algorithm types (e.g., ML/AI functionality 240) that generate and apply computerized models to simulate the human thought process in complex situations where the answers might be ambiguous and uncertain. A conventional cognitive algorithm includes self-learning technologies that use data mining, pattern recognition, natural language processing (NLP), and other related technologies to generate the mathematical models that make decisions (e.g., classifications, predictions, and the like) that, in effect, mimic human intelligence. In embodiments of the invention, the modifier “cognitive” as applied to “outputs” and/or “output actions” refers to the outputs, actions, and the like generated by cognitive algorithms to represent the result of the analysis operations performed by cognitive algorithms. A non-limiting example of a cognitive output action is determining the size and shape of candidate tiles 712 (shown in FIG. 7B), candidate tile regions 712B (shown in FIG. 7B), relevant tiles 1120 (shown in FIG. 11B), relevant tile top-down area 1120A (shown in FIG. 11B0, relevant tile regions 1120B (shown in FIG. 11B), and relevant tile groupings (e.g., relevant tile Group A region shown in FIG. 11B; and/or connected component Group AA shown in FIG. 10) (e.g., the novel tie net routing methodology 1160 shown in FIG. 11C).

In accordance with embodiments of the invention, the EDA system 210, and more specifically the CDM functionality 230 working in tandem with the novel tie-net routing functionality 248, use the operations described above to generate a routing plan 216 that includes tie net routings developed in accordance with aspects of the invention. Thus, the EDA system 210 provides a separate process for specialized tie net routing to the IC design power grid that can be integrated into the overall general routing processes of the IC design 212.

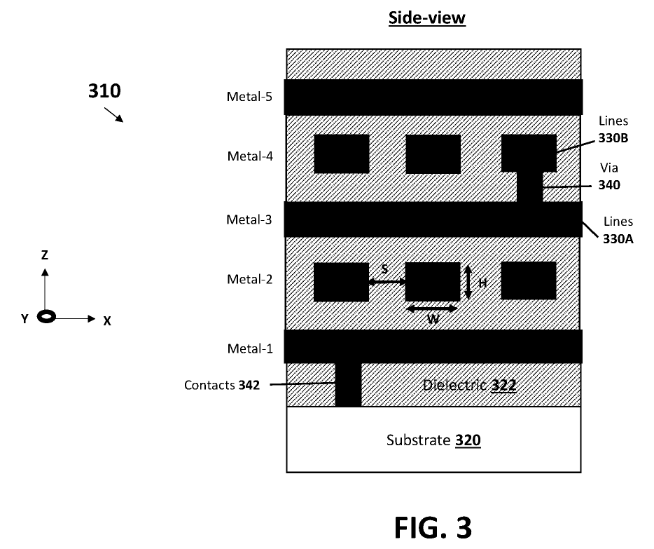

FIG. 3 depicts a simplified block diagram illustrating a side view of an IC 310 (e.g., a VLSI IC) to which tie net routing operations of aspects of the invention can be applied. It should be understood that, although the cross-sectional diagrams depicted in FIGS. 3-5, 12 and 13 are two-dimensional, the diagrams depicted in FIGS. 3, 4A, 4B, 5, 6, 7A, 7B, 8-10, 11A, and 11B are implemented as three-dimensional structures extending along a Y-axis, an X-axis, and a Z-axis, which are represented by the X/Y/Z axes depicted in these figures.

The IC 310 includes a substrate 320 (e.g., formed from silicon), multiple layers of dielectric material 322, a network of contacts 342 (for ease of illustration, only one is shown), a network of metal lines 330A extending along the X-axis, a network of metal lines 330B extending along the Y-axis, and a network of vias 340 (for ease of illustration, only one is shown), configured and arranged as shown. Sample line-related dimensions are shown, including S (space between metal lines, W (width of each metal line), and H (height of each metal line). Five metal layers of the IC 310 are shown and include Metal-1, Metal-2, Metal-3, Metal-4, Metal-5.

The metal layers (Metal-1, Metal-2, Metal-3, Metal-4, Metal-5) are used for various purposes, including interconnecting different components and creating the required circuit paths. In accordance with aspects of the invention, selected the metal layers are also part of the power grid of the IC 310 and used to distribute power to the various components, including component inputs that must be tied. The most visible metal layers are located on the top surface of the IC 310. These are the layers typically formed in the BEOL or final stages of the IC chip design process. The metal layers are situated between different layers of the dielectric (insulating) material (e.g., dielectric material 322). The first level metal layer (Metal-1) is directly above the substrate 320 and is often used for connecting transistors within a small area. The subsequent metal layers (Metal-2, Metal-3, Metal-4, Metal-5) are used for routing signals between different parts of the IC 310 and connecting to various components. Each layer is separated by the dielectric material 322 to prevent electrical shorting between the metal layers.

The IC 310 is a hierarchical design including cell/module regions (not shown separately) organized as parent cells and child cells. The parent-child cell/module relationship in the IC 310 reflects a hierarchical and functional decomposition where the parent module integrates and manages child modules to create a complete and functional design. The parent cell/module is the higher-level cell/module in the IC design hierarchy. The parent cell/module encompasses a larger portion of the IC 310 and is responsible for integrating various sub-modules to form a complete functional unit. The child cell/module is a lower-level module within the parent cell/module used to achieve the parent’s overall functionality. For example, a parent cell/module can represent a complex subsystem like a microprocessor, and the microprocessor could be made up of child modules like arithmetic logic units (ALUs), registers, and cache controllers.

Routing operations applied during design of the IC 310 provide systems and methods for controlling the “resources” that are provided to a parent cell/module from a child cell/module. In the routing stage of designing the IC 310, “resources” from a child cell/module to a parent cell/module generally refer to design data and information that facilitate the integration and optimization of the IC 310. Such resources can include routing data (e.g., netlist information, placement data, etc.), design constraints (e.g., design rules, timing constraints, etc.), routing constraints (e.g., layer usage, congestion areas, etc.), electrical characteristics (e.g., resistance and capacitance information; signal integrity requirements; and the like), design hierarchy information (e.g., hierarchical relationships, interface specification, etc.), design and verification data (e.g., design verification results, design changes, design updates, etc.), and integration information (e.g., integration constraints, etc.).

More specifically, for netlist information, the netlist includes the list of electrical connections between different components in the child cell/module. This information helps the parent cell/module understand how to integrate these connections into the overall design of the IC 310. For placement data, the positions of components within the child cell/module are provided, which can be used to determine the layout of interconnects (e.g., lines 330A, 330B, vias 340). For design rules, constraints related to line spacing (S), line width (W), line height (H) and other design rules specific to the child cell/module are passed up to the parent cell/module. These constraints ensure that the routing in the parent cell/module adheres to the required design specifications. For timing constraints, information about critical paths and timing requirements within the child cell/module helps the parent cell/module meet overall performance goals. For metal layer usage, information on the metal layers used within the child cell/module and their specific routing needs is communicated to the parent cell/module. This includes details on layer assignments for different types of interconnects. For congestion areas, information on areas where routing congestion is anticipated within the child cell/module is passed to the parent cell/module. This helps the parent cell/module manage and plan routing to avoid conflicts. Data on electrical characteristics of the interconnects in the child cell/module, such as capacitance and resistance, is provided to manage signal integrity and ensure that the overall IC design meets electrical performance requirements.

For signal integrity requirements, information about signal integrity concerns, such as crosstalk or noise issues, is shared with the parent cell/module to ensure that these issues are addressed in the broader IC design. For hierarchical relationships, details about the hierarchical structure of the IC design, including how child cells/modules fit into the parent cell/module, are provided. This helps in understanding how routing in the child cell/module impacts the parent design. For interface specifications, information on the interfaces between child cells/modules and the parent cell/module, including connection points and required routing paths, is communicated. For design verification results, any verification or validation results from the child cell/module are provided to the parent cell/module. This includes information about rule violations or issues detected during verification. For design changes and updates, changes/updates made in the child cell/module during the design process are communicated to the parent cell/module, ensuring that the parent cell/module reflects the latest design modifications. For integration constraints, specific constraints related to how the child cell/module integrates with the parent cell/module, such as alignment or connectivity constraints, are provided.

Embodiments of the invention route unused or floating pins of an IC design (e.g., IC design 212 shown in FIG. 2) to the IC design power grid to ensure correct behavior. Each instance of such a gate input is referred to as being “tied,” and the connections that form the ties are referred to as tie nets. Tie net modeling is a technique performed by router software during the place-and-route process of IC design operations to connect tie nets.

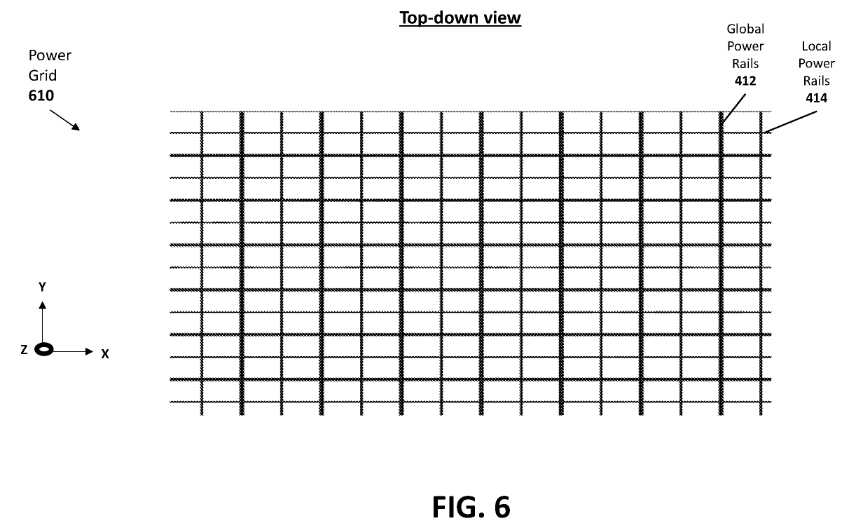

FIGS. 4A, 4B, 5, and 6 depict the major components that form a power grid 610 (shown in FIG. 6) of an IC design. More specifically, the power grid 610 includes a global power rail network 410 formed from global power rails 412 (shown in isolation in FIG. 4A) a local power rail network 420 formed from local power rails 414 (shown in isolation in FIG. 4B), and a power staple network 510 (shown in FIG. 5). FIG. 4A depicts a simplified block diagram illustrating a top-down view of the global power rails 412. Each global power rail 412 has a length dimension (L1), a width dimension W1, and a height dimension (e.g., H shown in FIG. 3). The global power rails 412 form part of a global power rail network 410 that functions as a primary power distribution network that delivers electrical power to various parts of IC and ensures that power is supplied efficiently and consistently across the IC. Similar to global interconnects, global power rails 412 are designed to cover extensive areas of the IC and provide power to multiple regions and components, such as logic gates, memory cells, and input/output (I/O) blocks. In some embodiments, there are separate global power rails for the supply voltage (VDD) and ground (GND). The global power rails 412 are conventionally implemented using the higher metal layers in the IC (e.g., Metal-4, Metal-5 shown in FIG. 3), which are wider and thicker to handle higher currents and minimize voltage drops across the chip.

The global power rails 412 of the global power rail network 410 are connected (e.g., through the power staple network 510 shown in FIG. 5) to the local power rails 414 of the local power rail network 420 shown in FIG. 4B. The local power rails 414 distribute power to individual blocks or cells within the IC. Unlike the global power rails 412, which cover large areas of the IC, the local power rails 414 are designed for more localized power distribution of specific functional blocks or regions within the IC, such as individual cells, memory arrays, or specific logic blocks. The local power rails 414 typically use intermediate or lower metal layers (e.g., Metal-1, Metal-2 shown in FIG. 3), which are less wide and less thick than the higher metal layers. By providing power closer to the components, the local power rails 414 help reduce the voltage drop that occurs over long distances in the global power rails 412, thereby ensuring stable operation within localized regions. The local power rails 414 allow for more flexible and optimized power distribution, tailored to the specific needs and power requirements of different parts of the IC. Local power rails 414 improve power delivery performance of the overall power grid 610 by minimizing voltage drops and noise, thereby ensuring that the power supply is stable and reliable for sensitive or high-performance blocks of the IC design. The local power rails 414 can assist with managing power distribution on the IC more efficiently by delivering it directly to the components that need it, thereby reducing unnecessary power loss.

FIG. 5 depicts a simplified diagram illustrating the power staple network 510 formed from power staples 512. Similar to the function performed by vias 340 (shown in FIG. 3), power staples 512 are metal structures that provide a path for power to move from one power rail at one level of the IC to another power rail at another level of the IC. The power staples 512 are not visible in the power grid 610 (shown in FIG. 6) because the power staples are between two power rails in an area where the two power rails overlap one another. The power staples 512 are strategically placed within the power grid 610 layout to maintain a continuous and stable power supply throughout the IC.

A non-limiting example of how the novel tie-net routing functionality 248 (shown in FIG. 2) can be performed in accordance with aspects of the invention is depicted by the methodology 1160 shown in FIG. 11C, and FIGS. 7A, 7B, 8-10, 11A and 11B depict various concepts and structures that implement the methodology 1160. The following description of the steps/operations of the methodology 1160 will reference both the methodology 1160 and the associated structure/element/concept in FIGS. 7A, 7B, 8-10, 11A and 11B.

Referring initially to FIG. 11C, STEP-01 of the methodology 1160 collects relevant tiles, along with tie-pins in or associated with the tiles. The executing STEP-01 of the methodology 1160 begins by electronically segmenting the IC design 212 (shown in FIG. 2) into candidate tiles, non-limiting examples of which are depicted by the candidate tile network 710 and candidate tiles 712 shown in FIGS. 7A and 7B. In general, the term “tile” is used in IC design to refer to a modular, repeating unit or block used to construct larger sections of the IC design 212. Tiles are designed to be repetitive and modular, allowing them to be easily replicated and assembled to form complex circuit layouts. This modularity simplifies the design and layout process. Each tile typically represents a specific functional block or component of the IC design, such as memory cells, logic gates, or analog circuits. Tiles can be customized for different functions depending on their role in the chip. Using tiles helps in optimizing the layout by enabling systematic arrangement and alignment, which can improve the overall efficiency and organization of the chip design. By adjusting the number and arrangement of tiles, designers can scale up or down the complexity and size of the IC design. The use of tiles can facilitate automated design processes, such as placement and routing, by providing standardized building blocks that can be processed consistently.

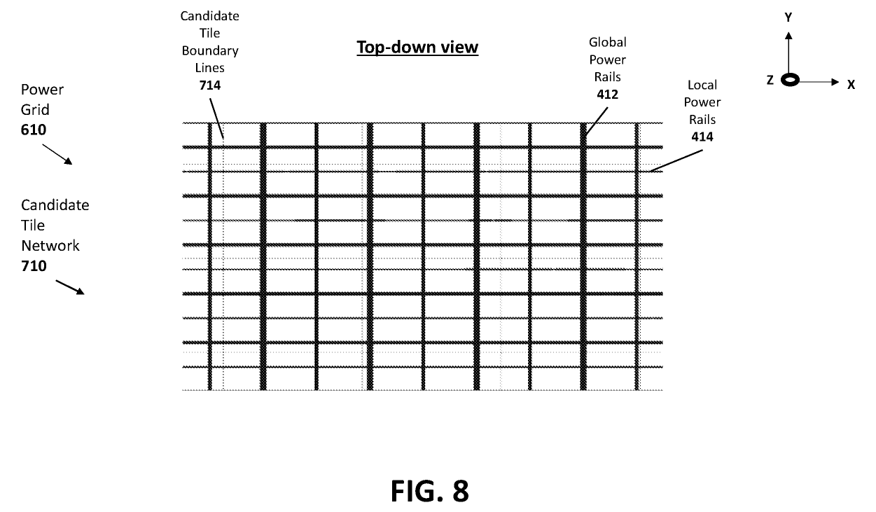

The tiles depicted in FIGS. 7A, 7B, and 8 are defined as candidate tiles 712 because they represent a pool of tiles from which relevant tiles (e.g., relevant tiles 1120, 1130, 1140, 1150 shown in FIG. 11A) will be selected in accordance with embodiments of the invention. In some embodiments of the invention, the EDA system 210, including specifically the novel tie-net routing functionality 248, organize the IC design 212 into the candidate tile network 710 of candidate tiles 712. In the embodiments depicted in FIGS. 7A, 7B and 8, the candidates tiles 712 are substantially square or rectangular, and each candidate tile 712 include candidate tile boundary lines 714 and candidate tile corners 716. As best shown by the top-down view in FIG. 7B, each candidate tile 712 further includes a candidate tile top-down area 712A. As best shown by the side-down view in FIG. 7B, each candidate tile 712 further includes or defines a candidate tile region 712B positioned beneath the candidate tile 712 and extending for a predetermined distance into the IC design. For example, in some embodiments of the invention, the predetermined distance extends along the Z-axis to a lowest point of the IC design (e.g., into the FEOL region of the IC design) where a tie-pin is located. In some embodiments of the invention, the candidate tiles 712 are positioned such that all of the tie-pins in the IC design are below the candidate tile 712. In some embodiments of the invention, if the candidate tiles 712 are positioned such that all of the tie-pins in the IC design are not below the candidate tile 712, the candidate tile region 712B can also extend above the candidate tile 712 along the Z-axis to a highest point of the IC design where a tie-pin is located.

In FIG. 8, continuing with STEP-01 of the methodology 1160, the methodology 1160 electronically overlays the power grid 610 with the candidate tile network 710, and evaluates each of the candidate tiles 712 based at least in part on a spatial relationship between the candidate tile 712 and tie-pins of the IC design 212. In some embodiments of the invention, if a tie-pin or preexisting wire or global wire of the IC design 212 satisfies a predetermined spatial relationship with respect to a candidate tile 712, the candidate tile 712 is marked or otherwise reclassified as a “relevant” tile (e.g., the relevant tiles 1120, 1130, 1140, 1150 shown in FIGS. 11A and 11B. In some embodiments of the invention, if none of the tie-pins or preexisting wire or global wire in the IC design 212 satisfy the predetermined spatial relationship with respect to the candidate tile 712, the candidate tile 712 is not marked or otherwise reclassified as a “relevant” tile. In some embodiments of the invention, the predetermined spatial relationship corresponds to an electronic tile region (e.g., candidate tile region 712B) defined for a given candidate tile 712. In some embodiments of the invention, the methodology 1160 defines an electronic version of a candidate tile region 712B for the candidate tile 712 currently under evaluation; the predetermined spatial relationship between a tie-pin or preexisting wire or global wire of the IC design 212 and a candidate tile 712 is satisfied when at least one of the IC design tie-pins or preexisting wire or global wire is within the candidate tile region 712B, and the predetermined spatial relationship between the IC design tie-pin or preexisting wire or global wire and the candidate tile 712B is not satisfied when none of the IC design tie-pins or preexisting wire or global wire is within the candidate tile region 712B. At this stage of the evaluation performed by the novel tie net routing functionality 248 and the methodology 1160, a set of relevant tiles 1120 (shown in FIG. 11A), relevant tile regions 1120B and their associated tie-pins or preexisting wire or global wire of the IC design 212 are identified and associated with one another.

The novel tie net routing functionality and the methodology 1160 also electronically associate each relevant tile 1120 with a section of the IC design power grid 610 (e.g., as shown in FIG. 8). Similar to the technique/functionality used to determine the candidate tiles 712 that are marked or classified as relevant tiles 1120, the methodology 1160 associates each relevant tile 1120 with a selected segment of the IC design power grid 610, where the selected segment of the IC design power grid 610 is selected based at least in part on the relevant tile’s spatial relationship with respect to the selected segment of the IC design power grid 610. In some embodiments of the invention, if a segment of the IC design power grid 610 satisfies a predetermined spatial relationship with respect to the relevant tile (e.g., relevant tile 1120), the segment of the IC design power grid 610 is selected, the relevant tile (e.g., relevant tile 1120) and the selected segment of the IC design power grid 610 are associated with one another, and the portions of the IC design power grid 610 that do not fall within the selected segment of the IC design power grid 610 are not associated with the relevant tile (e.g., relevant tile 1120). In some embodiments of the invention, the predetermined spatial relationship corresponds to the electronic tile region (e.g., relevant tile region 1120B shown in FIG. 11B) defined for a given relevant tile (e.g., relevant tile 1120 shown in FIG. 11B). In some embodiments of the invention, the predetermined spatial relationship between a segment of the IC design power grid 610 and the relevant tile 1120 that is currently under evaluation is satisfied by the selected segment of the IC design power grid 610 being within the relevant tile region 1120B. At this stage of the evaluation performed by the novel tie net routing functionality 248 and the methodology 1160, the set of relevant tiles (e.g., relevant tile 1120), the associated relevant tile regions (e.g., 1120B), the associated tie-pins (or preexisting wire or global wire), and the associated selected segment of the IC design power grid 610 are all identified and associated with one another. In some embodiments of the invention, constraints (e.g., the constraints shown in FIG. 11D) are applied to the selection of the segment of the IC design power grid 610. For example, the novel tie net routing functionality 248 and the methodology 1160 can be prohibited or constrained from selecting a segment of the IC design power grid 610 that splits a power rail (e.g., global power rail 412 and/or local power rail 414 shown in FIGS. 4A and 4B) of the power grid 610 along its length dimension (e.g., along the L1 dimension shown in FIG. 4A; and/or the L2 dimension shown in FIG. 4B). As another example, the novel tie net routing functionality 248 and the methodology 1160 can be prohibited or constrained from selecting a segment of the IC design power grid 610 that splits a power staple 512 of the power grid 612 along any dimension thereof.

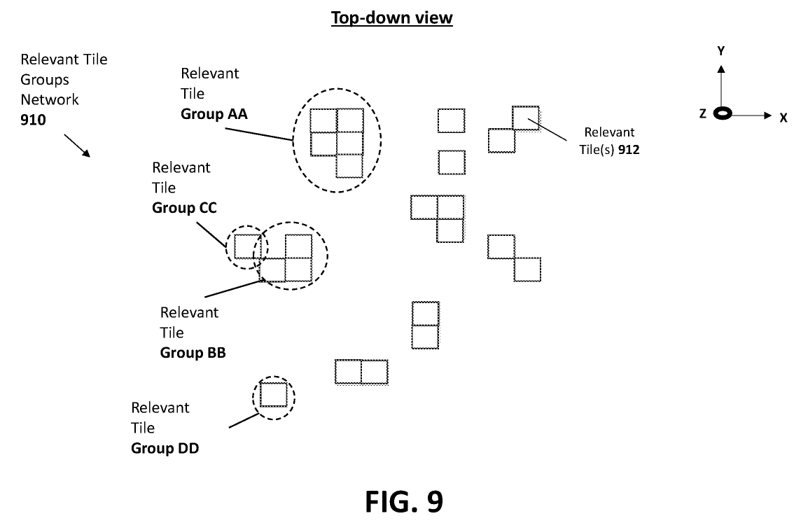

The novel tie net routing functionality 248 and the methodology 1160 (e.g., STEP-03 thereof) also electronically associate or group the relevant tiles (e.g., 1120, 1130, 1140, 1150 (shown in FIG. 11A) based at least in part on a spatial relationship between the relevant tiles. Non-limiting examples of such relevant tile groupings are depicted in FIGS. 9, 11A and 11B. For example, in FIG. 9, which shows a relevant tiles group network 910, the candidate tiles 712 that were not marked as “relevant” have been eliminated from the evaluation, and only relevant tiles 912 are shown. Relevant tiles 912 are grouped using the grouping operations described herein to form relevant tile groupings, examples of which are marked in FIG. 9 as Relevant Tile Group AA, Relevant Tile Group BB, Relevant Tile Group CC, and Relevant Tile Group DD. Additional examples of relevant tile groupings are shown in FIG. 11A and marked as Relevant Tile Group A and Relevant Tile Group B. FIG. 11A further illustrates examples of structures that have been associated with each relevant tile 1120, 1130, 1140, 1150 using, for example, the previously described spatial relationships that are used to mark or otherwise label the candidate tiles as relevant tiles. Relevant tile 1120 is associated with power grid segment(s) 1122, tie-pins/nodes 1124, and global wires and pre-wires (or preexisting wires) 1126. The global wires and pre-wires 1126, 1136, 1146, 1156 represent tie-net routings/connections that have been determined by other parts of the overall routing processes of the IC design 212. Thus, the novel tie-net routing functionality 248 and the methodology 1160 cans begin with certain tie-net relationships already set. Relevant tile 1130 is associated with power grid segment(s) 1132, tie-pins/nodes 1134, and global wires and pre-wires 1136. Relevant tile 1140 is associated with power grid segment(s) 1142, tie-pins/nodes 1144, and global wires and pre-wires 1146. Relevant tile 1150 is associated with power grid segment(s) 1152, tie-pins/nodes 1154, and global wires and pre-wires 1156. FIG. 11A further depicts the relevant title Group A region formed from the individual relevant tile regions (e.g., relevant tile region 1120B) that make up a tile group. In embodiments of the invention, the relevant tile group region bounds the options for where on the IC power grid a tie-pin can be routed. In accordance with embodiments of the invention, and as described in greater detail herein, tie-pins in a given group can only be routed to a segment of the power grid that is within the same group as the tie-pin. In embodiments of the invention, non-relevant tile regions 1129 are also identified using embodiments of the invention, non-relevant tile regions 1129 are excluded from inclusion in the relevant tile group A region.

In embodiments of the invention, the relevant tiles (e.g., relevant tiles 912) are grouped along with the associated relevant tile regions (e.g., relevant tile regions 1120B), the associated tie-pins (or preexisting wire or global wire), and the associated selected segment of the IC design power grid 610. In some embodiments of the invention, the relevant tiles include tile boundary lines (e.g., tile boundary lines 1121 shown in FIG. 11B), and the predetermined spatial relationship corresponds to relevant tiles 912 that share a tile boundary line. In some embodiments of the invention, the predetermined spatial relationship is satisfied and relevant tiles are included within a group if the relevant tile shares a tile boundary line with any one of the relevant tiles in the group. At this stage of the evaluation performed by the novel tie net routing functionality 248, the set of relevant tiles are organized into groups (e.g., Relevant Tile Group AA, Relevant Tile Group BB, Relevant Tile Group CC, and Relevant Tile Group DD sown in FIG. 9) (e.g., using a breadth first search algorithm or other suitable algorithm for determining connected components); and the associated relevant tile regions of the group, the associated tie-pins of the group, and the associated selected segment(s) of the IC design power grid 610 of the group are all identified and associated with one another.

The novel tie net routing functionality 248 and the methodology 1160 (STEP-03 and STEP-04) apply a routing operation (e.g., any suitable routing algorithm) that routes the tie-pins in each group to an appropriate location of the segment(s) of the IC design power grid in the same group as the tie-pin, thereby forming Relevant Tiles & Net Shapes & Power Grid 1010 (shown in FIG. 10) formed from connected component groups (e.g., Connected Components Group AA, Connected Components Group BB, Connected Components Group CC, Connected Components Group DD shown in FIG. 10), net shapes (not shown separately), and segments of the power grid 810 . In general, the net shapes are the geometric layout of a signal or power connection between or to components on the chip. In some embodiments of the invention, the tie-pin routing can be multi-threaded in that groups are all routed substantially in parallel. After routing each group, the resulting tie net routes are added to the original tie net of the IC design 212. As described at STEP-04 of the methodology 1160, for each connected component group, a source pin is created from the power grid shapes; all of the pins in the group are added; and the resulting part of the tie net is routed or scheduled for multi-threaded (e.g., substantially parallel) routing along all other nets.

As previously noted, FIG. 11D summarizes non-limiting examples of constraints that can be applied to the novel tie-net routing functionality 248 and the methodology 1160 in accordance with embodiments of the invention. Under constraint (a) when collecting relevant tiles, existing global wiring and tie-pin assignments are factored in at the beginning of the methodology 1160; (b) when splitting rails of the power grid, power rails are split in a sensible way. In particular, power rails are not split along the rail’s length dimension, and power staples are not split at all; (c) to calculate connected components, all relevant tiles are stored in a map where the key is the area of the tile (e.g., relevant tile top-down area 1120A), and the methodology 1160 can for any given tile check if the neighbors are in the map of relevant tiles, and with this information a “breadth first search” can be performed as part of connecting the components; and (d) after routing parts of tie-nets, the resulting routes are added to the original tie net.

Thus, it can be seen from the foregoing detailed description that the novel tie net routing functionality 248 and the methodology 1160 can segment tie nets in a way that in most cases allows efficient parallelization of the routing of the tie net while increasing the likelihood (through the predetermined spatial relationships) that there is no loss in performance or quality of the tie net routing solution generated. Alternatively, a guarantee in parallelization efficiency can be obtained by sacrificing a controlled amount of potential solution quality (increase in wire length). Embodiments of the invention partition the routing space into rectangular tiles; all tiles are marked that are intersected by a tie-pin or a tie global route; the power grid is split at the tile borders; and search connected components on the marked tiles. Embodiments of the invention route each connected component within its associated group, individually. By tuning tile size, embodiments of the invention can obtain strong parallelization while substantially increasing the likelihood that there is no loss in tie net distribution quality. Embodiments of the invention can also be forced to split connected components that are too large (e.g., exceed a predetermined tile region size threshold), which sacrifices a limited amount of solution quality and guarantees strong speed gains from parallelization.

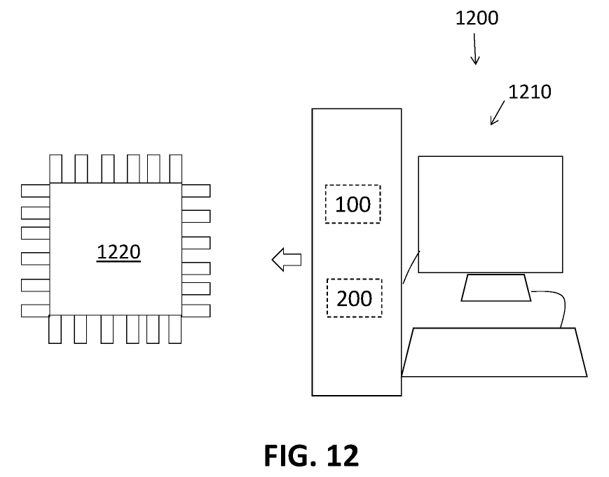

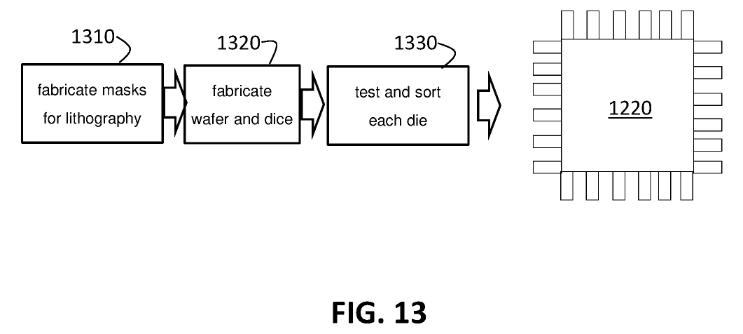

FIG. 12 is a block diagram of a system 1200 to perform various IC design operations, including executing the code block 200 operable to implement the novel additional pessimism removal functionality described herein. The system 1200 includes processing circuitry 1210 used to generate the design that is ultimately fabricated into an IC 1220. The steps involved in the fabrication of the IC 1220 are well-known and briefly described herein. Once the physical layout is finalized, based, in part, on the low-latency HSS operations according to embodiments of the invention to facilitate optimization of the routing plan, the finalized physical layout is provided to a foundry. Masks are generated for each layer of the IC based on the finalized physical layout. Then, the wafer is processed in the sequence of the mask order. The processing includes photolithography and etch. This is further discussed with reference to FIG. 13.

FIG. 13 is a process flow of a method of fabricating the IC 1220 according to exemplary embodiments of the invention. Once the physical design data is obtained, based, the integrated circuit 1220 can be fabricated according to known processes that have been previously described herein, and that are generally described with reference to FIG. 13. Generally, a wafer with multiple copies of the final design is fabricated and cut (i.e., diced) such that each die is one copy of the IC 1220. At block 1310, the processes include fabricating masks for lithography based on the finalized physical layout. At block 1320, fabricating the wafer includes using the masks to perform photolithography and etching. Once the wafer is diced, testing and sorting each die is performed, at block 1330, to filter out any faulty die.

For the sake of brevity, conventional techniques related to making and using aspects of the invention may or may not be described in detail herein. In particular, various aspects of computing systems and specific computer programs to implement the various technical features described herein are well known. Additionally, conventional techniques related to semiconductor device and IC design and fabrication may or may not be described in detail herein. Moreover, the various tasks and process steps described herein can be incorporated into a more comprehensive procedure or process having additional steps or functionality not described in detail herein. Thus, in the interest of brevity, many conventional implementation details are only mentioned briefly herein or are omitted entirely without providing the well-known system and/or process details.

Many of the functional units of the systems described in this specification have been labeled as modules. Embodiments of the invention apply to a wide variety of module implementations. For example, a module can be implemented as a hardware circuit including custom VLSI circuits or gate arrays, off-the-shelf semiconductors such as logic chips, transistors, or other discrete components. A module can also be implemented in programmable hardware devices such as field programmable gate arrays, programmable array logic, programmable logic devices or the like. Modules can also be implemented in software for execution by various types of processors. An identified module of executable code can, for instance, include one or more physical or logical blocks of computer instructions which can, for instance, be organized as an object, procedure, or function. Nevertheless, the executables of an identified module need not be physically located together but can include disparate instructions stored in different locations which, when joined logically together, function as the module and achieve the stated purpose for the module.

The components/modules of the systems illustrated herein are depicted separately for ease of illustration and explanation. In embodiments of the invention, the functions performed by the components/modules can be distributed differently than shown without departing from the scope of the various embodiments of the invention describe herein unless it is specifically stated otherwise.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ± 8% or 5%, or 2% of a given value.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

It will be understood that those skilled in the art, both now and in the future, may make various improvements and enhancements which fall within the scope of the claims which follow.

What is claimed is:

1. A computer-implemented method of performing circuit design operations, the computer-implemented method comprising:
defining, using a processor system, relevant tiles of an electronic version of a circuit design;
performing, using the processor system, a grouping operation on the relevant tiles to define relevant-tile groups; and
performing iterations of a tie-pin routing operation, wherein each of the iterations of the tie-pin routing operation comprises:
identifying an initial or next relevant-tile group; and
routing tie-pins of the initial or next relevant-tile group to a segment of a power grid of the circuit design of the initial or next relevant-tile group, wherein the tie-pins of the initial or next relevant-tile group and the segment of the power grid of the circuit design are within a relevant-tile group region of the initial or next relevant-tile group.

2. The computer-implemented method of claim 1, wherein defining, using the processor system, the relevant tiles comprises defining, using the processor system, candidate tiles of the electronic version of the circuit design.

3. The computer-implemented method of claim 2, wherein each of the candidate tiles includes an associated candidate tile region.

4. The computer-implemented method of claim 3, wherein defining, using the processor system, the relevant tiles is based at least in part on determining a subset of the candidate tiles, wherein the subset is selected from the group consisting of at least one tie-pin, preexisting wire, and global wire within the associated candidate tile region of the candidate tile in the subset of candidate tiles.

5. The computer-implemented method of claim 1, wherein the iterations of the tie-pin routing operation are performed substantially in parallel.

6. The computer-implemented method of claim 1, wherein the relevant-tile group region of the initial or next relevant-tile group is substantially below the initial or next relevant-tile group.

7. The computer-implemented method of claim 1, wherein:
the segment of the power grid is determined based at least in part on predetermined segment selection rules that comprises prohibited segment selection operations; and
the prohibited segment selection operations comprise a selection operation that splits a power rail of the power grid along a length dimension of the power rail.

8. A computer system comprising a processor system electronically connected to a memory, wherein the processor system is operable to perform processor system operations operable to perform circuit design operations, the processor system operations comprising:
defining relevant tiles of an electronic version of a circuit design;
performing a grouping operation on the relevant tiles to define relevant-tile groups; and
performing iterations of a tie-pin routing operation, wherein each of the iterations of the tie-pin routing operation comprises:
identifying an initial or next relevant-tile group; and
routing tie-pins of the initial or next relevant-tile group to a segment of a power grid of the circuit design of the initial or next relevant-tile group, wherein the tie-pins of the initial or next relevant-tile group and the segment of the power grid of the circuit design are within a relevant-tile group region of the initial or next relevant-tile group.

9. The computer system of claim 8, wherein defining the relevant tiles comprises defining candidate tiles of the electronic version of the circuit design.

10. The computer system of claim 9, wherein each of the candidate tiles includes an associated candidate tile region.

11. The computer system of claim 10, wherein defining the relevant tiles is based at least in part on determining a subset of the candidate tiles, wherein the subset is selected from the group consisting of at least one tie-pin, preexisting wire, and global wire within the associated candidate tile region of the candidate tile in the subset of candidate tiles.

12. The computer system of claim 8, wherein the iterations of the tie-pin routing operation are performed substantially in parallel.

13. The computer system of claim 8, wherein the relevant-tile group region of the initial or next relevant-tile group is substantially below the initial or next relevant-tile group.

14. The computer system of claim 8, wherein:
the segment of the power grid is determined based at least in part on predetermined segment selection rules that comprises prohibited segment selection operations; and
the prohibited segment selection operations comprise a selection operation that splits a power rail of the power grid along a length dimension of the power rail.

15. A computer program product comprising a computer readable program stored on a computer readable storage medium, wherein the computer readable program, when executed on a processor system, causes the processor system to perform processor system operations operable to perform circuit design operations, the processor system operations comprising:
defining relevant tiles of an electronic version of a circuit design;
performing a grouping operation on the relevant tiles to define relevant-tile groups; and
performing iterations of a tie-pin routing operation, wherein each of the iterations of the tie-pin routing operation comprises:
identifying an initial or next relevant-tile group; and
routing tie-pins of the initial or next relevant-tile group to a segment of a power grid of the circuit design of the initial or next relevant-tile group, wherein the tie-pins of the initial or next relevant-tile group and the segment of the power grid of the circuit design are within a relevant-tile group region of the initial or next relevant-tile group.

16. The computer program product of claim 15, wherein:
defining the relevant tiles comprises defining candidate tiles of the electronic version of the circuit design; and
each of the candidate tiles includes an associated candidate tile region.

17. The computer program product of claim 16, wherein defining the relevant tiles is based at least in part on determining a subset of the candidate tiles, wherein the subset is selected from the group consisting of at least one tie-pin, preexisting wire or global wire within the associated candidate tile region of the candidate tile in the subset of candidate tiles.

18. The computer program product of claim 15, wherein the iterations of the tie-pin routing operation are performed substantially in parallel.

19. The computer program product of claim 15, wherein the relevant-tile group region of the initial or next relevant-tile group is substantially below the initial or next relevant-tile group.

20. The computer program product of claim 15, wherein:
the segment of the power grid is determined based at least in part on predetermined segment selection rules that comprises prohibited segment selection operations; and
the prohibited segment selection operations comprise a selection operation that splits a power rail of the power grid along a length dimension of the power rail.
